(19) United States
(12) Patent Application Publication
(10) Pub. No.: US 2025/0199952 A1
(43) Pub. Date: Jun. 19, 2025

(54) IN MEMORY COLD PAGES DETECTOR

(71) Applicant: Micron Technology, Inc., Boise, ID (US)

(72) Inventors: Alessandro Orlando, Milan (IT); Danilo Caraccio, Milano (IT); Massimiliano Turconi, Gorgonzola (IT)

(21) Appl. No.: 18/970,255

(22) Filed: Dec. 5, 2024

Related U.S. Application Data
(60) Provisional application No. 63/610,186, filed on Dec. 14, 2023.

(51) Int. Cl. G06F 12/02; G06F 12/0864; G06F 12/122

(52) U.S. Cl. CPC G06F 12/0246; G06F 12/0864; G06F 12/122

(57) ABSTRACT

Apparatus and methods are disclosed, including receiving a memory operation that includes a memory address at the storage system; adding a page identifier (ID) of a page of memory containing the memory address to a cold list when the page ID is not already in the cold list, wherein the cold list includes memory pages accessed less frequently than other memory pages; removing the page ID from the cold list when the page ID is already in the cold list; and omitting the adding the page ID to the cold list when the page ID is not already in the cold list and the cold list is full.

### PRIORITY APPLICATION

This application claims the benefit of priority to U.S. Provisional Application Ser. No. 63/610,186, filed Dec. 14, 2023, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more memory systems (e.g., often non-volatile memory, such as flash memory, and may include volatile memory) that provide additional storage to retain data in addition to or separate from the main memory.

A memory system can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface). The memory controller can receive commands or operations from the host system in association with memory operations or instructions, such as read or write operations to transfer data (e.g., user data and associated integrity data, such as error data or address data, etc.) between the memory devices and the host device, erase operations to erase data from the memory devices, perform drive management operations (e.g., data migration, garbage collection, block retirement), etc.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example host system including a host device and a storage system.

FIG. 2 illustrates an example block diagram of a memory system.

FIG. 3 shows an example of memory for a host system.

FIG. 4 illustrates an example method of operating a memory system.

FIG. 5 is an illustration of an example of a cold list to contain page identifiers for cold memory pages.

FIG. 6 illustrates an example of a memory controller implementing a cold list in a memory system.

FIG. 7 illustrates an example of linked cold lists.

FIG. 8 is a flow diagram of another example of a method of operating a memory system.

FIG. 9 is an illustration of an example of a cold hash table to contain page identifiers for cold memory pages.

FIG. 10 illustrates an example of a memory controller implementing a cold hash table in a memory system.

FIG. 11 is an illustration of an example of a collision in implementing a cold hash table.

FIG. 12 illustrates an example of linked cold hash tables.

FIG. 13 illustrates another example block diagram of a host system.

### DETAILED DESCRIPTION

Software (e.g., programs), instructions, operating systems (OS), and other data are typically stored on storage systems and accessed for use by a host processor. Main memory (e.g., RAM) is typically faster, more expensive, and a different type of memory device (e.g., volatile) than a majority of the memory devices of the storage system (e.g., non-volatile, such as an SSD, etc.). In addition to the main memory, host systems can include different levels of volatile memory, such as a group of static memory (e.g., a cache, often SRAM), often faster than the main memory, in certain examples, configured to operate at speeds close to or exceeding the speed of the host processor, but with lower density and higher cost. Systems can include high speed, low latency compute express link (CXL) memory. The CXL provides a high capacity link between processors and the memory system. In other examples, more or less levels or quantities of main memory or static memory can be used, depending on desired host system performance and cost.

When the static memory is full, various replacement policies can be implemented to free static memory to improve system performance, often writing a portion of the static memory to the main memory or erasing that portion of the static memory depending on one or more factors, including least recently used (LRU) data, most recently used (MRU) data, first in first out (FIFO) data, last in first out (LIFO) data, least frequently used (LFU) data, random replacement (RR) data, etc. When the main memory is full, virtual space from the memory system can be allocated to supplement the main memory.

The memory system can also include different levels of memory cells. The different levels of memory cells can be of different memory types that involve different latencies in accessing types of memory cells. Additionally, the memory system can include memory that is disaggregated and access to the disaggregated memory involves different communication links.

The present inventors have recognized, among other things, that the memory system can be used to track the location of inactive or cold data. Cold data can include data that is inactive, unused, or has remained unchanged for a period of time. In other examples, cold data can include data that has been unused or has remained unchanged longer than other data in the storage system. Information regarding the location of cold data can be useful for optimizing system level page placement strategies. For example, a cold page of memory can be demoted to a slower tier of memory by the system to improve use of memory resources.

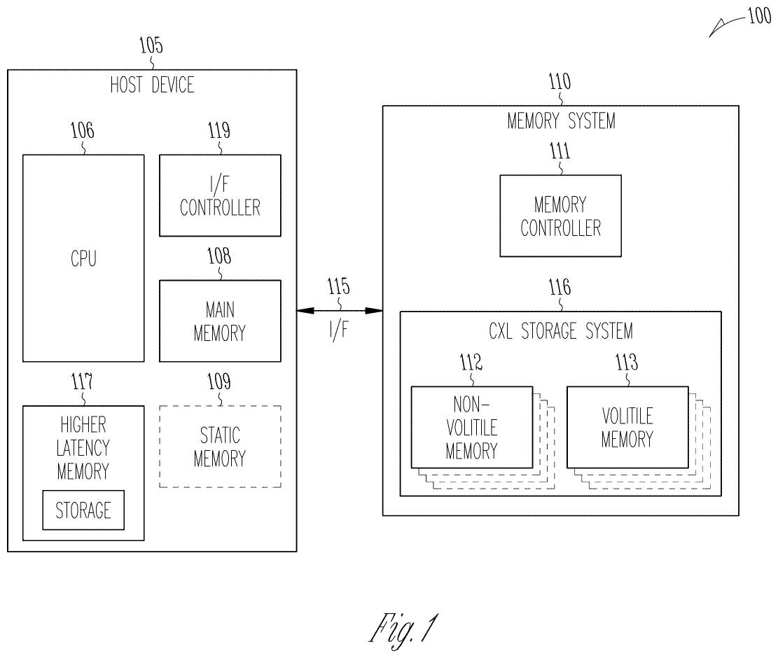

FIG. 1 illustrates an example system (e.g., a host system) 100 including a host device 105 and a memory system 110 and/or storage system 116 configured to communicate over a communication interface (I/F) 115 (e.g., a bidirectional parallel or serial communication interface). The host device 105 can include a host processor 106 (e.g., a host central processing unit (CPU) or other processor or processing device) or other host circuitry (e.g., a memory management unit (MMU), interface circuitry, assessment circuitry 107, etc.). In certain examples, the host device 105 can include a main memory 108 (e.g., DRAM, etc.) and optionally, a static memory 109, to support operation of the host processor 106.

The memory system 110 can include a universal flash storage (UFS) device, an embedded MMC (eMMC™) device, or one or more other memory devices. For example, if the memory system 110 includes a UFS device, the communication interface 115 (I/F) can include a serial bidirectional interface, such as defined in one or more Joint Electron Device Engineering Council (JEDEC) standards (e.g., JEDEC standard D223D (JESD223D), commonly referred to as JEDEC UFS Host Controller Interface (UFSHCI) 3.0, etc.). In another example, if the memory system 110 includes an eMMC device, the communication interface 115 can include a number of parallel bidirectional data lines (e.g., DAT[7:0]) and one or more command lines, such as defined in one or more JEDEC standards (e.g., JEDEC standard D84-B51 (JESD84-A51), commonly referred to as JEDEC eMMC standard 5.1, etc.). In other examples, the memory system 110 can include one or more other memory devices, or the communication interface 115 can include one or more other interfaces, depending on the host device 105 and the memory system 110.

The memory system includes a CXL storage system 116. The CXL storage system 116 can include one or both of volatile memory 113 and non- volatile memory 112. The CXL storage system 116 includes a high-capacity link between the memory controller 111 and the CXL storage system. To access the CXL storage system 116, the host device 105 sends instructions to a communication interface controller (119) that routes a CXL request to the memory controller 111. The host device may also include higher latency memory 117 having lower bandwidth than the CXL memory. Tiered memory is a generalizable memory architecture that leverages the heterogeneous power-performance characteristics of each tier. A tier can be an independent memory (e.g., Main memory, CXL, Storage) that is attached to the host device. The different tiers can have different latencies. In some examples, one or more tiers of the tiered memory can include non-volatile memory.

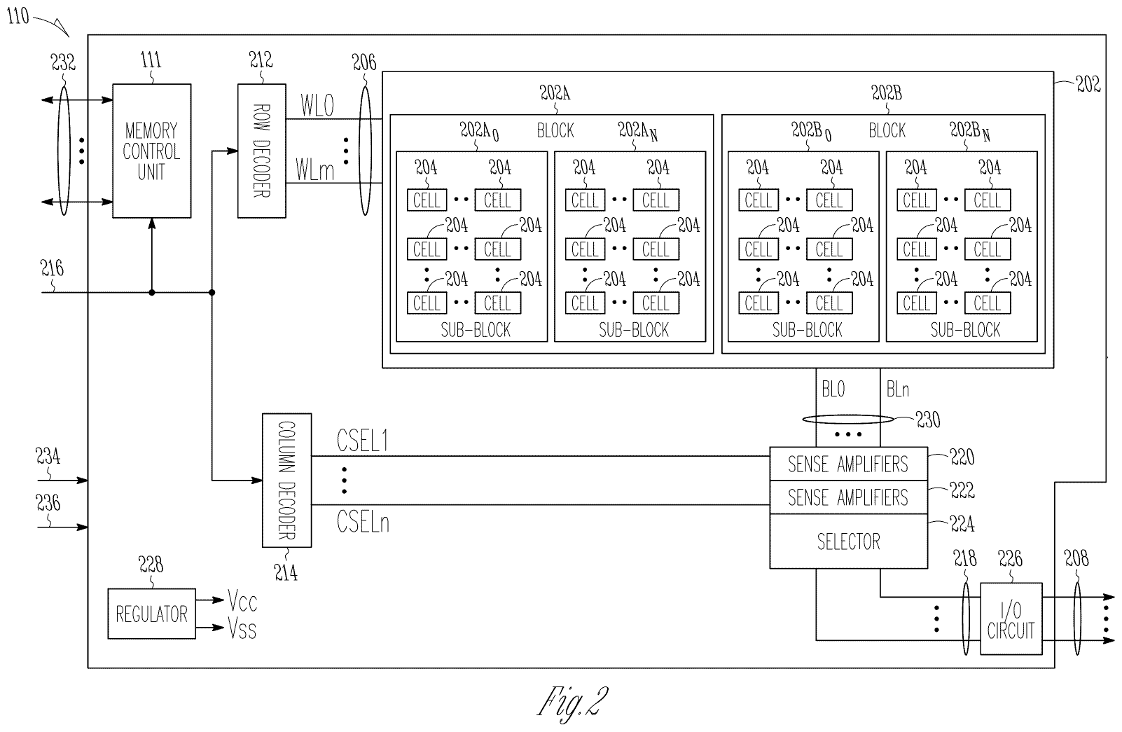

FIG. 2 illustrates an example block diagram of portions of a memory system 110 including a memory array 202 having a plurality of memory cells 204, and one or more circuits or components to provide communication with, or perform one or more memory operations on, the memory array 202. The memory array 202 can be included in the CXL memory or the higher latency memory 117. Although shown with a single memory array 202, in other examples, one or more additional memory arrays, dies, or LUNs can be included herein. The memory system 110 can include a row decoder 212, a column decoder 214, sense amplifiers 220, a page buffer 222, a selector 224, an input/output (I/O) circuit 226, and a memory controller 111.

The memory cells 204 of the memory array 202 can be arranged in blocks, such as first and second blocks 202A, 202B. Each block can include sub-blocks. For example, the first block 202A can include first and second sub-blocks 202A₀, 202Aₙ, and the second block 202B can include first and second sub-blocks 202B₀, 202Bₙ. Each sub-block can include a number of physical pages, each page including a number of memory cells 204. Although illustrated herein as having two blocks, each block having two sub-blocks, and each sub-block having a number of memory cells 204, in other examples, the memory array 202 can include more or fewer blocks, sub-blocks, memory cells, etc. In other examples, the memory cells 204 can be arranged in a number of rows, columns, pages, sub-blocks, blocks, etc., and accessed using, for example, access lines 206, first data lines 230, or one or more select gates, source lines, etc.

The memory controller 111 can control memory operations of the memory system 110 according to one or more signals or instructions received on control lines 232, including, for example, one or more clock signals or control signals that indicate a desired operation (e.g., write, read, erase, etc.), or address signals (A0-AX) received on one or more address lines 216. One or more devices external to the memory system 110 can control the values of the control signals on the control lines 232, or the address signals on the address line 216. Examples of devices external to the memory system 110 can include, but are not limited to, a host, a memory controller, a processor, or one or more circuits or components not illustrated in FIG. 2.

The memory system 110 can use access lines 206 and first data lines 230 to transfer data to (e.g., write or erase) or from (e.g., read) one or more of the memory cells 204. The row decoder 212 and the column decoder 214 can receive and decode the address signals (A0-AX) from the address line 216, can determine which of the memory cells 204 are to be accessed, and can provide signals to one or more of the access lines 206 (e.g., one or more of a plurality of word lines (WL0-WLm)) or the first data lines 230 (e.g., one or more of a plurality of bit lines (BL0-BLn)), such as described above.

The memory system 110 can include sense circuitry, such as the sense amplifiers 220, configured to determine the values of data on (e.g., read), or to determine the values of data to be written to, the memory cells 204 using the first data lines 230. For example, in a selected string of memory cells 204, one or more of the sense amplifiers 220 can read a logic level in the selected memory cell 204 in response to a read current flowing in the memory array 202 through the selected string to the data lines 230.

One or more devices external to the memory system 110 can communicate with the memory system 110 using the I/O lines (DQ0-DQN) 208, address lines 216 (A0-AX), or control lines 232. The input/output (I/O) circuit 226 can transfer values of data in or out of the memory system 110, such as in or out of the page buffer 222 or the memory array 202, using the I/O lines 208, according to, for example, the control lines 232 and address lines 216. The page buffer 222 can store data received from the one or more devices external to the memory system 110 before the data is programmed into relevant portions of the memory array 202, or can store data read from the memory array 202 before the data is transmitted to the one or more devices external to the memory system 110.

The column decoder 214 can receive and decode address signals (A0-AX) into one or more column select signals (CSEL1-CSELn). The selector 224 (e.g., a select circuit) can receive the column select signals (CSEL1-CSELn) and select data in the page buffer 222 representing values of data to be read from or to be programmed into memory cells 204. Selected data can be transferred between the page buffer 222 and the I/O circuit 226 using second data lines 218.

The memory controller 111 can receive positive and negative supply signals, such as a supply voltage (Vcc) 234 and a negative supply (Vss) 236 (e.g., a ground potential), from an external source or supply (e.g., an internal or external battery, an AC-to-DC converter, etc.). In certain examples, the memory controller 111 can include a regulator 228 to internally provide positive or negative supply signals.

Returning to the example system 100 of FIG. 1, the memory system 110 can include a memory controller 111 and multiple types of memory cells. In an example, the CXL memory can include one or both of non-volatile memory 112 and volatile memory 113, and can include a number of memory devices (e.g., dies or logical units (LUNs)) each including periphery circuitry thereon, and controlled by the memory controller 111. The tiered memory can include one or more ties of non-volatile memory. The non-volatile memory 112 can include one or more flash memory devices and the volatile memory 113 can include dynamic random access memory (DRAM).

Flash memory devices typically include one or more groups of one-transistor, floating gate memory cells. Two common types of flash memory array architectures include NAND and NOR architectures. The floating gate memory cells of the memory array are typically arranged in a matrix. The gates of each memory cell in a row of the array are coupled to an access line (e.g., a word line). In NOR architecture, the drains of each memory cell in a column of the array are coupled to a data line (e.g., a bit line). In NAND architecture, the drains of each memory cell in a column of the array are coupled together in series, source to drain, between a source line and a bit line.

Each memory cell in a NOR, NAND, 3D Cross Point (Xpoint), Holographic RAM (HRAM), MRAM, or one or more other architecture semiconductor memory array can be programmed individually or collectively to one or a number of programmed states. A single-level cell (SLC) can represent one bit of data per cell in one of two programmed states (e.g., 1 or 0). A multi-level cell (MLC) can represent two or more bits of data per cell in a number of programmed states (e.g., 2ⁿ, where n is the number of bits of data). In certain examples, MLC can refer to a memory cell that can store two bits of data in one of 4 programmed states. A triple-level cell (TLC) can represent three bits of data per cell in one of 8 programmed states. A quad-level cell (QLC) can represent four bits of data per cell in one of 16 programmed states. In other examples, MLC can refer to any memory cell that can store more than one bit of data per cell, including TLC and QLC, etc.

The memory system 110 can include a multimedia card (MMC) solid-state storage device (e.g., micro secure digital (SD) cards, etc.). MMC devices include a number of parallel interfaces (e.g., an 8-bit parallel interface) with a host device 105, and are often removable and separate components from the host device. In contrast, embedded MMC (eMMC) devices are attached to a circuit board and considered a component of the host device, with read speeds that rival serial ATA (SATA) based SSD devices. As demand for mobile device performance continues to increase, such as to fully enable virtual or augmented-reality devices, utilize increasing network speeds, etc., storage systems have shifted from parallel to serial communication interfaces. UFS devices, including controllers and firmware, communicate with a host device using a low-voltage differential signaling (LVDS) serial interface with dedicated read/write paths, further advancing read/write speeds between a host device and a storage system.

In three-dimensional (3D) architecture semiconductor memory device technology, vertical floating gate or charge trapping storage structures can be stacked, increasing the number of tiers, physical pages, and accordingly, the density of memory cells in a memory device.

To access the CXL memory the host device 105 sends instructions to an I/F controller 119. The I/F controller 119 will route CXL memory requests to the memory controller 111. The memory controller 111 can include, among other things, circuitry or firmware, such as a number of components or integrated circuits. For example, the memory controller 111 can include one or more memory controllers, circuits, or components configured to control access across the memory array and to provide a translation layer between the host device 105 and the memory system 110.

The non-volatile memory array 112 (e.g., a 3D NAND architecture semiconductor memory array) can include a number of memory cells arranged in, for example, a number of devices, planes, blocks, or physical pages. As one example, a TLC memory device can include 18,592 bytes (B) of data per page, 1536 pages per block, 548 blocks per plane, and 4 planes per device. As another example, an MLC memory device can include 18,592 bytes (B) of data per page, 1024 pages per block, 548 blocks per plane, and 4 planes per device, but with half the required write time and twice the program/erase (P/E) cycles as a corresponding TLC memory device. Other examples can include other numbers or arrangements.

Different types of memory cells or memory arrays can provide for different page sizes, or may require different amounts of metadata associated therewith. For example, different memory device types may have different bit error rates, which can lead to different amounts of metadata necessary to ensure integrity of the page of data (e.g., a memory device with a higher bit error rate may require more bytes of error correction code data than a memory device with a lower bit error rate). As an example, an MLC NAND flash device may have a higher bit error rate than a corresponding SLC NAND flash device. As such, the MLC device may require more metadata bytes for error data than the corresponding SLC device.

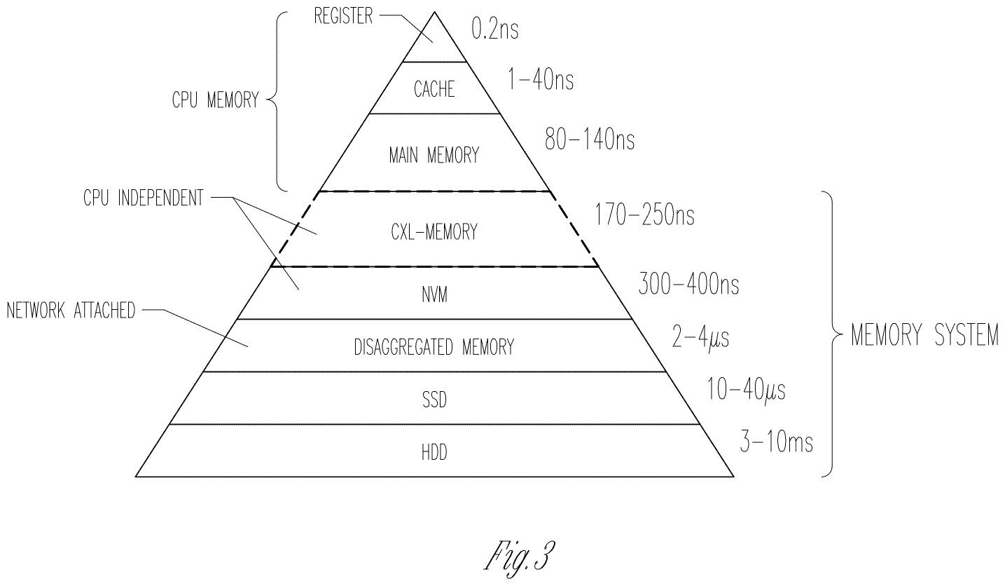

FIG. 3 shows an example of memory for the system 100 of FIG. 1. The host device 105 can include register memory, cache memory, and main memory. The memory system 110 can include CXL memory, non-volatile memory (NVM), disaggregated memory that is accessed through a network, solid state drive (SSD) memory, and hard disk drive (HDD) memory. The tiers of memory are shown with the fast access (and lowest latency) type of memory towards the top and slower access (and higher latency) memory towards the bottom. The illustration of FIG. 3 also shows that there is less faster memory than slower memory in the system 100.

In view of the tiered organization of memory of the system 100, optimized placement of pages in appropriate types of memory can help optimize performance of the system 100. For example, memory pages that are accessed the most often should be placed in memory with the fastest access. Conversely, memory pages that are accessed seldomly, should be placed in memory with slower access. Information about the access frequency of memory pages, or about which memory pages were most recently accessed is useful to memory resource management by the system 100.

Cold pages can be defined as memory pages that have been accessed once and not accessed again for more than a predetermined time interval (e.g., 1 minute). Pages that are cold shouldn't occupy the higher performance memory. The host operating system (host OS) could be tasked with tracking which pages are cold in memory. However, the host OS typically only has an approximate idea of “coldness” of memory pages. Associating an OS virtual page to a specific device or specific memory device would be time consuming, resource expensive, and in some cases not possible. Additionally, the memory device cannot leverage the OS page information to execute proactive memory management strategies (e.g., page compression, etc.). The present inventors have recognized that having the memory system 110 track the cold pages of memory can provide information to improve system performance.

FIG. 4 is a flow diagram of an example of a method 400 of operating a storage system (e.g., the memory system 110 in FIG. 1). The storage system includes a memory controller (e.g., memory controller 111 in FIG. 1) and one or more memory arrays. In some examples, the storage system includes multiple types of memory in the one or more memory arrays, with some types of the memory having slower access than other types of memory. The memory controller arranges the one or more memory arrays into memory pages and produces a cold list containing page identifiers (page IDs) of cold memory pages.

At block 405, the memory controller receives a memory operation from the host device (e.g., host device 105 in FIG. 1). The memory operation can be a new memory read request or a memory write request and includes a memory address. At block 410, the memory controller determines the page identifier (page ID) for the memory page containing the memory address. The page ID can be the page address aligned to the page granularity of the host operating system page ID size (e.g., 4 KB of data to a memory page). The page ID granularity can be configurable in the memory controller (e.g., by firmware or software). For example, if the memory is CXL memory interleaved with a granularity of 2 KB, the page ID reflects the 2 KB granularity.

At block 415, the memory controller checks if the page ID for the memory operation is already in the cold list (CL). If the page ID for the memory operation is in the list, at block 420 the page ID is removed or evicted from the cold list because the memory page is no longer cold. And the process returns block 405 to wait for the next memory operation.

At block 425, the memory controller checks if the cold list is full. If the cold list is full, the page ID for the memory operation is not added to the cold list and the process returns to block 405. The page ID will not be colder than the pages already in the list, and the cold list will still contain page IDs for the coldest memory pages. At block 430, the memory controller inserts the page ID into the cold list if the page ID is not already in the cold list and the cold list is not full. The size of the cold list can be a parameter configurable in the memory controller.

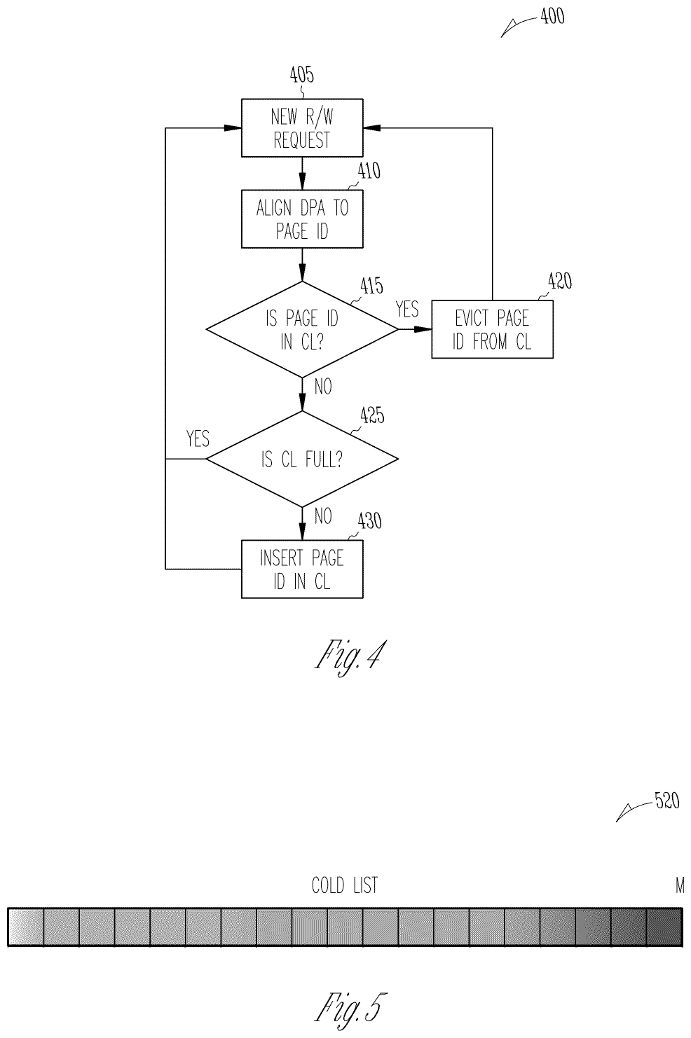

FIG. 5 is an illustration of an example of a cold list 520 that can hold M page IDs, where M is an integer. In the example, M=15 for simplicity of the drawing. In an actual implementation, the number of entries M in the cold list 520 may be many thousands. The Mth entry on the right of the list in the example contains the page ID of the coldest page in the memory device. Page ID entries may be shifted to the head of the cold list (to the right in the illustration in FIG. 5) as page IDs are evicted from the list and new page IDs are shifted into the cold list tail. The cold list 520 may be implemented in content addressable memory (CAM). The memory controller searches for the page ID to locate the page ID in the cold list 520. The page IDs may identify memory pages from more than one type of memory. For instance, the page IDs may identify memory pages of CXL memory and non-volatile memory.

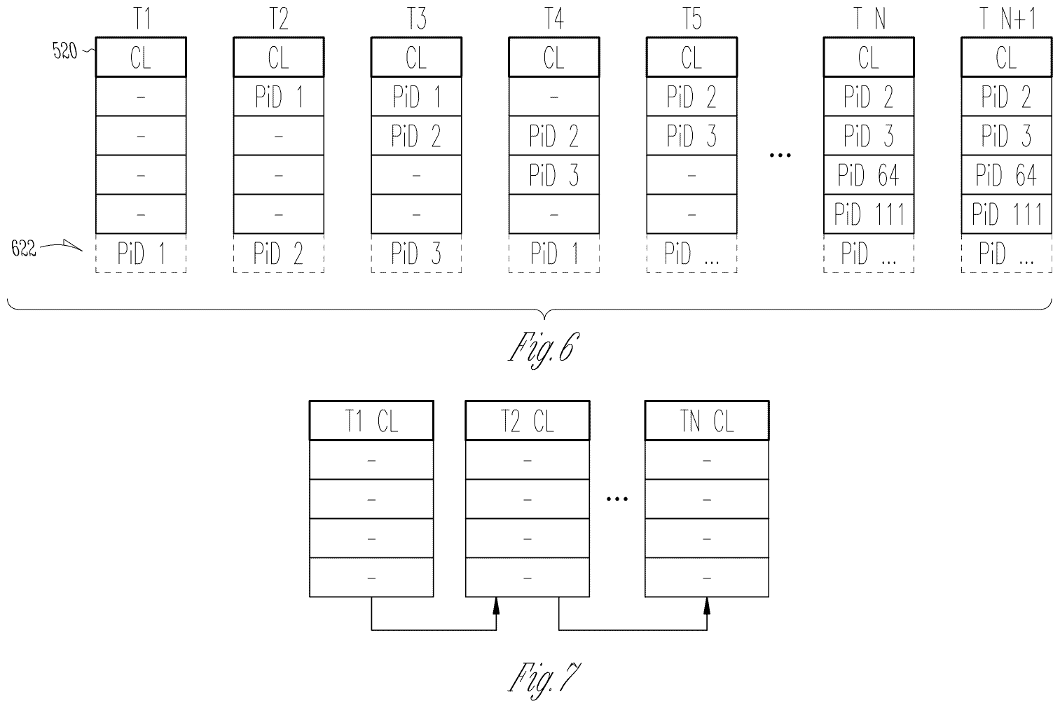

FIG. 6 illustrates an example of a memory controller implementing a cold list 520 in a storage system over multiple memory operations (T1 to TN+1).

The example shows a cold list (CL) of only four elements (M=4) for simplicity of the drawings. At T1, a memory operation 622 accesses the memory page corresponding to Page ID 1 (PiD1), and PiD1 is inserted into the cold list. At T2, a memory operation accesses PiD2, and PiD2 is inserted into the cold list that already holds PiD1, and at T3, a memory operation accesses PiD3, and PiD3 is inserted into the cold list that holds PiD1 and PiD2.

At T4, a memory operation accesses PiD1 again and PiD1 is evicted from the cold list. Eviction can be performed in any position of the cold list. At T5, PiD2 and PiD3 are the coldest pages in the cold list and memory operations continue. At TN, the cold list is full after N page ID insertions and PiD2 and PiD3 are still the coldest pages in the cold list and have not been accessed since T2 and T3. At TN+1, page IDs that do not fit into the cold list are discarded because the page IDs in the cold list identify the coldest pages. Additional page IDs can be inserted into the cold list when there is an eviction of a page ID.

The cold list is coherent with the memory page operations of the host device. The host device may move memory pages in the system through promotion or demotion to different types of memory. For example, the host device may read the cold list stored in the system storage. Based on the information in the cold list, the host device may demote one or both of page ID 2 and Page ID 3 from non-volatile memory to disaggregated memory of the storage system. When the host device removes a memory page it is also removed from the cold list. The memory controller or the host device may reset (e.g., clear) the cold list if the memory pages for the page IDs are removed from the storage system (e.g., because all the pages of the cold list have been compressed).

In some examples, the memory controller implements multiple cold lists (e.g., in CAM). The multiple cold lists may have different classes. For example, one class of cold list may hold page IDs of memory pages that have been accessed only once. A second class of cold list may hold page IDs of memory pages that have been accessed twice but not accessed again. The cold lists may be linked so that page IDs are transferred from the first class of cold list to the second class of cold list.

FIG. 7 illustrates an example of N classes of linked cold lists. Cold list T1 contains page IDs of memory pages that have been accessed only once. Cold list T2 contains page IDs of memory pages that have been accessed twice. Cold list T2 is linked to cold list T1. When a page ID of cold list T1 is evicted, it is moved to cold list T2 instead of being discarded. Page IDs evicted from cold list T2 are moved to linked cold list T3, and so on to linked cold list TN, and after eviction from cold list TN, the page ID is no longer considered cold. The multiple classes of cold lists provide more information concerning access to the memory pages. For instance, the host device can tell how often a memory page has been accessed by the class of a cold list that contains its page ID.

While implementing a cold list in CAM provides advantages, CAM in a system is typically a limited memory resource. To track a large quantity of cold memory pages, another approach implements cold lists in static random access memory (SRAM). A hash table can be used to implement a cold list in SRAM as a cold hash table. Each entry of the cold hash table includes a page ID of the memory page accessed and a timestamp of the access. The position of an entry in the cold hash table is determined by applying the page ID to a hash function to produce a page ID hash. The page ID is then inserted with the timestamp into the cold hash table using the page ID hash as an index into the cold hash table. Other approaches to implementing cold lists in SRAM include, among other things, using a log buffer and using bloom filters.

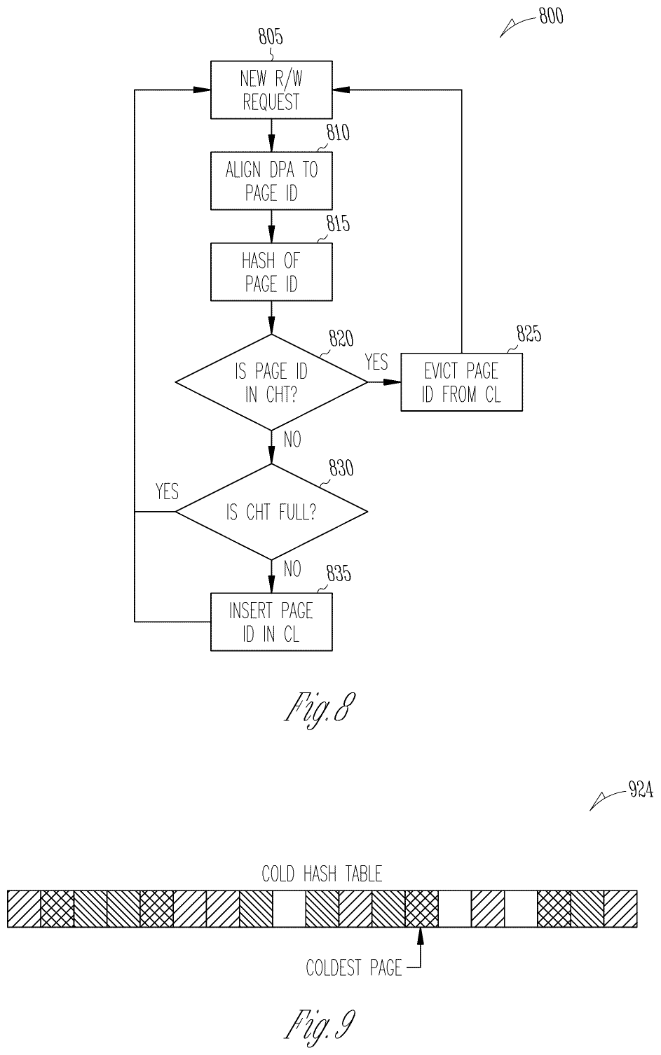

FIG. 8 is a flow diagram of another example of a method 800 of operating a memory device of a storage system (e.g., the memory system 110 in FIG. 1). The memory controller arranges the one or more memory arrays into memory pages and produces a cold hash table containing page IDs of cold memory pages. The cold hash table may contain memory pages that were accessed one time and then not accessed again.

At block 805, the memory controller receives a memory operation from the host device. At block 810, the memory controller determines the page identifier (page ID) for the memory page containing the memory address (e.g., by aligning the page address to the page ID granularity).

At block 815, a page ID hash is determined by applying the page ID to the hash function for the cold hash table. At block 820, the memory controller checks if the page ID for the memory operation is already in the cold hash table (CHT). If the page ID for the memory operation is in the list, at block 825 the page ID is removed or evicted from the cold hash table because the memory page is no longer cold. The process returns block 805 to wait for the next memory operation.

At block 830, the memory controller checks if the cold hash table is full. If the cold hash table is full, the page ID for the memory operation is not added to the cold hash table and the process returns to block 805. The page ID will not be colder than the pages already in the hash table, and the cold hash table will still contain page IDs for the coldest memory pages. At block 830, the memory controller inserts the page ID into the cold hash table if the page ID is not already in the cold hash table and the cold hash table is not full.

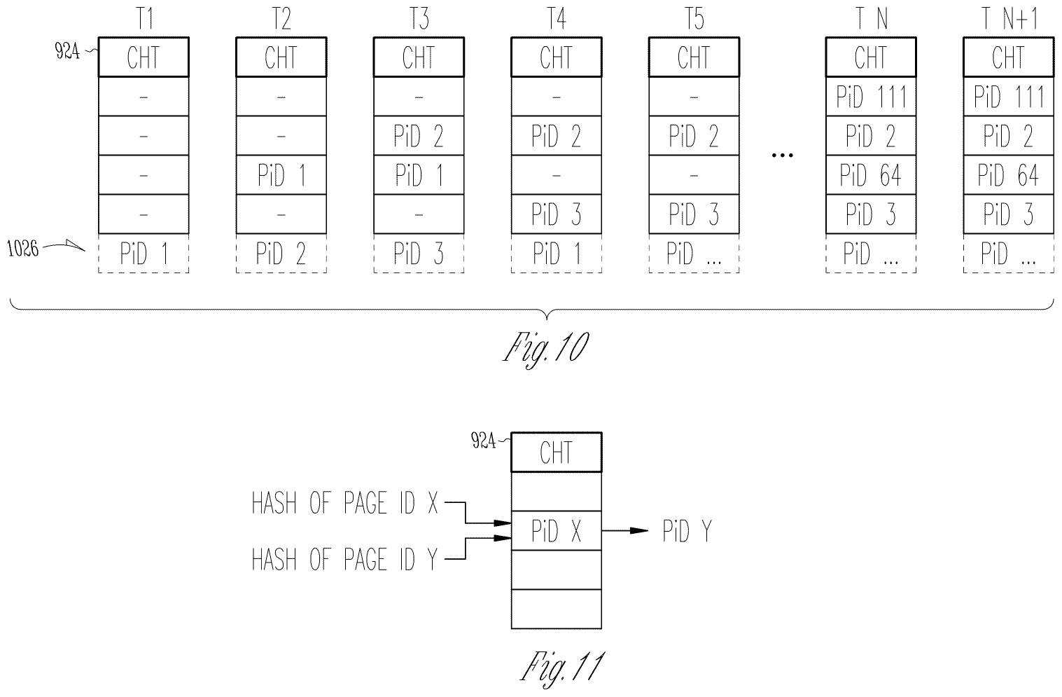

FIG. 9 is an illustration of an example of a cold hash table that can hold M page IDs. The memory controller searches the whole cold hash table to determine if a page ID is in the table. The arrow indicates the table entry of the coldest page of the M pages in the hash table. Unlike the cold list example of FIG. 5, the position in the cold hash table does not reflect coldness of the corresponding memory page. If the host device wants to know the page ID of the coldest page in the table, the host device would read the timestamps of the entries in the table to find the coldest page.

FIG. 10 illustrates an example of a memory controller implementing a cold hash table 924 in a storage system over multiple memory operations (T1 to TN+1). The example shows a cold hash table (CHT) of only four elements (M=4) for simplicity of the drawings. At T1, a memory operation 1026 accesses the memory page corresponding to Page ID 1 (PiD1), and PiD1 is inserted into the cold hash table according to a hash of PiD1. At T2, a memory operation accesses PiD2, and PiD2 is inserted into the cold hash table that already holds PiD1, and at T3, a memory operation accesses PiD3, and PiD3 is inserted into the cold hash table holds PiD1 and PiD2.

At T4, a memory operation accesses PiD1 again and PiD1 is evicted from the cold hash table. Eviction can be performed in any position of the cold hash table. At T5, PiD2 and PiD3 are the coldest pages in the cold hash table and memory operations continue. At TN, the cold hash table is full after N page ID insertions, and PiD2 and PiD3 are still the coldest pages in the cold hash table and have not been accessed since T2 and T3. At TN+1, page IDs that do not fit into the cold list are discarded because the page IDs currently in the cold hash table identify the coldest pages. Additional page IDs can be inserted into the cold hash table when there is an eviction of a page ID from the table.

Using a cold hash table to track page IDs of cold memory pages can involve collisions in the cold hash table. A collision occurs when the hash function produces the same page ID hash for two different page IDs. When there is a collision, a page ID that should not be removed from the hash table may be erroneously removed.

To detect collisions, the memory controller determines the location of a new entry in the cold hash table using the hash of the page ID of the new entry. The memory controller reads the contents of the location in the cold hash table indexed by the page ID hash. If the indexed location is empty, the memory controller inserts the page ID into the indexed location. If the indexed location is not empty and the contents of the table entry is a different page ID, then a collision is detected.

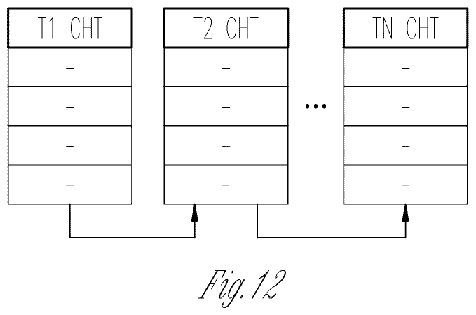

To resolve a collision, the memory controller concatenates the page ID of the new entry to the previous page ID that is already in the cold hash table 924, thus building a separate chaining solution for entries that collide. FIG. 11 is an illustration of an example of a collision in the cold hash table 924. In the example, Page ID X (PiD X) is already included in the cold hash table 924, and Page ID Y is the new entry for the cold hash table 924. There is a collision because the hash of Page ID Y is the same as the hash of Page ID X. PiD Y (and its corresponding timestamp) is placed in a chained list entry determined by the concatenation (PiD X, PiD Y). Because the cold hash table has M entries, the chained list can be M elements long. If the chained list becomes full, no more collisions can be resolved, and any new page ID that results in a collision is discarded.

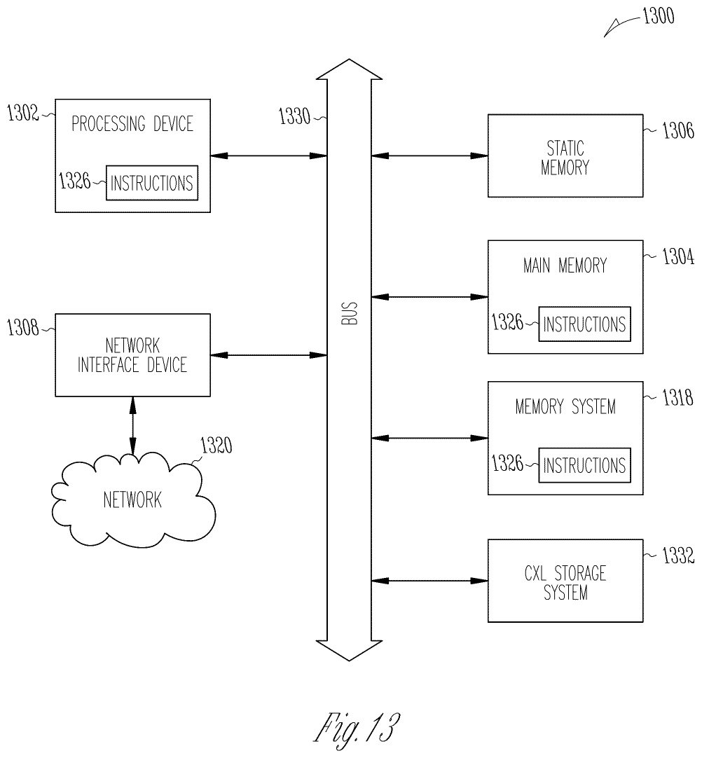

Similar to the cold lists of FIG. 7, multiple cold hash tables can be linked and the linked cold hash tables may have different classes. FIG. 12 shows an example of N classes of linked cold hash tables. Cold hash table T1 contains page IDs of memory pages that have been accessed only once. Cold hash table T2contains page IDs of memory pages that have been accessed twice. Cold hash table T2 is linked to cold hash table T1. When a page ID of cold hash table T1 is evicted, it is moved to cold hash table T2 instead of being discarded. Page IDs evicted from cold hash table T2 are moved to linked cold hash table T3, and so on to linked cold hash table TN. After eviction from cold hash table TN, the page ID is no longer considered cold.

Having the memory system track the coldest memory pages of the system allows for system level page placement strategies to optimize memory resources. The storage system or a host OS can use the cold page information to improve memory page placement strategies such as demoting coldest pages to a slower tier of memory in the system. In some examples, the storage system can send cold page information to the host, which can make further decisions on page placement. In some examples, the storage system can execute proactive memory management strategies such as page compression, or memory demotion to enhance or balance wear on the memories.

FIG. 13 illustrates a block diagram of an example machine (e.g., a host system) 1300 upon which any one or more of the techniques (e.g., methodologies) discussed herein may perform. In alternative embodiments, the machine 1300 may operate as a standalone device or may be connected (e.g., networked) to other machines. In a networked deployment, the machine 1300 may operate in the capacity of a server machine, a client machine, or both in server-client network environments. In an example, the machine 1300 may act as a peer machine in peer-to-peer (P2P) (or other distributed) network environment. The machine 1300 may be a personal computer (PC), a tablet PC, a set-top box (STB), a personal digital assistant (PDA), a mobile telephone, a web appliance, an loT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 1300 may include a processing device 1302 (e.g., a hardware processor, a central processing unit (CPU), a graphics processing unit (GPU), a hardware processor core, or any combination thereof, etc.), a main memory 1304 (e.g., read-only memory (ROM), dynamic random-access memory (DRAM) such as synchronous DRAM (SDRAM) or Rambus DRAM (RDRAM), etc.), a static memory 1306 (e.g., static random-access memory (SRAM), etc.), a memory system 1318, and a CXL storage system 1332, some or all of which may communicate with each other via a communication interface (e.g., a bus) 1330.

The processing device 1302 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1302 can also be one or more special-purpose processing devices such as an application specific integrated circuit (ASIC), a field programmable gate array (FPGA), a digital signal processor (DSP), network processor, or the like. The processing device 1302 can be configured to execute instructions 1326 for performing the operations and steps discussed herein. The computer system 1300 can further include a network interface device 1308 to communicate over a network 1320.

The memory system 1318 can include a machine-readable storage medium (also known as a computer-readable medium) on which is stored one or more sets of instructions 1326 or software embodying any one or more of the methodologies or functions described herein. The instructions 1326 can also reside, completely or at least partially, within the main memory 1304 or within the processing device 1302 during execution thereof by the computer system 1300, the main memory 1304 and the processing device 1302 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1300 may further include a display unit, an alphanumeric input device (e.g., a keyboard), and a user interface (UI) navigation device (e.g., a mouse). In an example, one or more of the display units, the input device, or the UI navigation device may be a touch screen display. The machine may include a signal generation device (e.g., a speaker), or one or more sensors, such as a global positioning system (GPS) sensor, compass, accelerometer, or one or more other sensors. The machine 1300 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1326 (e.g., software, programs, an operating system (OS), etc.) or other data stored on the storage system 1318 can be accessed by the main memory 1304 for use by the processing device 1302. The main memory 1304 (e.g., DRAM) is typically fast, but volatile, and thus a different type of storage than the storage system 1318 (e.g., an SSD), which is suitable for long-term storage, including while in an “off” condition. The instructions 1326 or data in use by a user or the machine 1300 are typically loaded in the main memory 1304 for use by the processing device 1302. When the main memory 1304 is full, virtual space from the memory system 1318 can be allocated to supplement the main memory 1304; however, because the memory system 1318 device is typically slower than the main memory 1304, and write speeds are typically at least twice as slow as read speeds, use of virtual memory can greatly reduce user experience due to storage system latency (in contrast to the main memory 1304, e.g., DRAM). Further, use of the storage system 1318 for virtual memory can greatly reduce the usable lifespan of the storage system 1318.

The instructions 1324 may further be transmitted or received over a network 1320 using a transmission medium via the network interface device 1308 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1308 may include one or more physical jacks (e.g., Ethernet, coaxial, or phone jacks) or one or more antennas to connect to the network 1320. In an example, the network interface device 1308 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1300, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to--direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” and “substrate” are used herein to refer generally to any structure on which integrated circuits are formed, and also to such structures during various stages of integrated circuit fabrication. The following detailed description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells (e.g., NAND strings of memory cells). As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

As used herein, directional adjectives, such as horizontal, vertical, normal, parallel, perpendicular, etc., can refer to relative orientations, and are not intended to require strict adherence to specific geometric properties, unless otherwise noted. For example, as used herein, a vertical structure need not be strictly perpendicular to a surface of a substrate but may instead be generally perpendicular to the surface of the substrate, and may form an acute angle with the surface of the substrate (e.g., between 60 and 120 degrees, etc.).

In some embodiments described herein, different doping configurations may be applied to a select gate source (SGS), a control gate (CG), and a select gate drain (SGD), each of which, in this example, may be formed of or at least include polysilicon, with the result such that these tiers (e.g., polysilicon, etc.) may have different etch rates when exposed to an etching solution. For example, in a process of forming a monolithic pillar in a 3D semiconductor device, the SGS and the CG may form recesses, while the SGD may remain less recessed or even not recessed. These doping configurations may thus enable selective etching into the distinct tiers (e.g., SGS, CG, and SGD) in the 3D semiconductor device by using an etching solution (e.g., tetramethylammonium hydroxide (TMCH)).

Operating a memory cell, as used herein, includes reading from, writing to, or erasing the memory cell. The operation of placing a memory cell in an intended state is referred to herein as “programming,” and can include both writing to or erasing from the memory cell (i.e., the memory cell may be programmed to an erased state).

According to one or more embodiments of the present disclosure, a memory controller (e.g., a processor, controller, firmware, etc.) located internal or external to a memory device, is capable of determining (e.g., selecting, setting, adjusting, computing, changing, clearing, communicating, adapting, deriving, defining, utilizing, modifying, applying, etc.) a quantity of wear cycles, or a wear state (e.g., recording wear cycles, counting operations of the memory device as they occur, tracking the operations of the memory device it initiates, evaluating the memory device characteristics corresponding to a wear state, etc.)

According to one or more embodiments of the present disclosure, a memory access device may be configured to provide wear cycle information to the memory device with each memory operation. The memory device control circuitry (e.g., control logic) may be programmed to compensate for memory device performance changes corresponding to the wear cycle information. The memory device may receive the wear cycle information and determine one or more operating parameters (e.g., a value, characteristic) in response to the wear cycle information.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

Example 1 includes subject matter (such as a storage system) comprising a processor and a memory array including multiple memory cells. The processor is configured to produce a cold list of memory pages of the memory array indicating cold memory pages accessed less frequently than other memory pages, including add a page identifier (ID) of a memory page to the cold list in response to receiving a memory operation containing a memory address included in the memory page when the page ID is not already in the cold list, and remove the page ID from the cold list when the page ID is already in the cold list.

In Example 2, the subject matter of Example 1 optionally includes a the processor configured to omit the adding the page ID to the cold list when the page ID is not already in the cold list and the cold list is full.

In Example 3, the subject matter of Example 1 optionally includes the processor configured to add the page ID to the cold list by inserting the page ID in a tail of the cold list.

In Example 4, the subject matter of one or any combination of Examples 1-3 optionally includes the processor configured to produce a cold list that is a cold hash table, determine a page ID hash using the page ID and a hash function, and add the page ID to cold list by inserting the page ID into the cold hash table using the page ID hash as an index into the cold hash table.

In Example 5, the subject matter of Example 4 optionally includes processor configured to insert the page ID into the cold hash table when a cold hash table entry indexed by the page ID hash is empty, and concatenate the page ID to a previous page ID previously stored at the cold hash table entry indexed by the page ID hash when the cold hash table entry is not empty.

In Example 6, the subject matter of one or both of Examples 4 and 5 optionally includes the processor configured to discard the page ID when a cold hash table entry indexed by the page ID hash is not empty and the cold hash table is full.

In Example 7, the subject matter of one or any combination of Examples 4-6 optionally includes the processor configured to include a timestamp of the memory operation with the page ID in the cold hash table.

Example 8 includes subject matter (such as a method of operating a storage system) or can optionally be combined with one or any combination of Examples 1-7 to include such subject matter, comprising receiving a memory operation at the storage system, wherein the memory operation includes a memory address; adding a page identifier (ID) of a page of memory containing the memory address to a cold list when the page ID is not already in the cold list, wherein the cold list includes memory pages accessed less frequently than other memory pages; removing the page ID from the cold list when the page ID is already in the cold list; and omitting the adding the page ID to the cold list when the page ID is not already in the cold list and the cold list is full.

In Example 9, the subject matter of Example 8 optionally includes inserting the page ID to a tail of the cold list.

In Example 10, the subject matter of one or both of Examples 8 and 9 optionally includes removing the page ID from the cold list and adding the page ID to a linked cold list.

In Example 11, the subject matter of one or any combination of Examples 8-10 optionally includes adding the page ID to a cold list stored in content addressable memory (CAM) of the memory device.

In Example 12, the subject matter of one or any combination of Examples 8-11 optionally includes inserting the page ID into a cold hash table.

In Example 13, the subject matter of Example 12 optionally includes determining a page ID hash using the page ID and a hash function, and inserting the page ID into the cold hash table using the page ID hash as an index into the cold hash table.

In Example 14, the subject matter of Example 13 optionally includes inserting the page ID into the cold hash table when a cold hash table entry indexed by the page ID hash is empty, and concatenating the page ID to a previous page ID previously stored at the cold hash table entry indexed by the page ID hash when the cold hash table entry is not empty.

In Example 15, the subject matter of Example 14 optionally includes discarding the page ID when the cold hash table entry is not empty and the cold hash table is full.

In Example 16, the subject matter of one or any combination of Examples 13-15 optionally includes inserting the page ID and a timestamp of the memory operation in a cold hash table entry indexed by the page ID hash.

In Example 17, the subject matter of one or any combination of Examples 8-16 optionally includes receiving at the storage system a request from a host device to read at least a portion of the cold list, and receiving a memory operation from the host device to move a page of memory having a page ID included in the cold list from a first type of memory to a second type of memory, wherein access to the first type of memory has lower latency than access to the second type of memory.

Example 18 includes subject matter (such as a host system) or can optionally be combined with one or any combination of Examples 1-17 to include such subject matter, comprising a host device including a host processor and a storage system. The storage system includes at least a first memory array and a memory controller. The first memory array includes a first type of memory cells and a second memory array having a second type of memory cells, wherein latency to access the first memory is less than latency to access the second memory. The memory controller is configured to receive a memory operation from the host processor, wherein the memory operation includes a memory address; add a page identifier (ID) of a page of memory containing the memory address to a cold list when the page ID is not already in the cold list, wherein the cold list includes memory pages access less frequently than other memory pages; remove the page ID from the cold list when the page ID is already in the cold list; and omit the adding the page ID to the cold list when the page ID is not already in the cold list and the cold list is full.

In Example 19, the subject matter of Example 18 optionally includes a host processor configured to move the page of memory from the first memory to the second memory in response to the page ID being added to the cold list.

In Example 20, the subject matter of one or both of Examples 18 and 19 optionally includes a memory controller configured to determine a page ID hash using the page ID and a hash function, and insert the page ID with a timestamp into an element of the cold list indexed in the cold list using the page ID hash when the page ID is not already in the cold list.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A storage system comprising:
a memory array including multiple memory cells; and
a processor configured to produce a cold list of memory pages of the memory array indicating cold memory pages accessed less frequently than other memory pages, including:
add a page identifier (ID) of a memory page to the cold list in response to receiving a memory operation containing a memory address included in the memory page when the page ID is not already in the cold list; and
remove the page ID from the cold list when the page ID is already in the cold list.

2. The storage system of claim 1, wherein the processor is configured to omit the adding the page ID to the cold list when the page ID is not already in the cold list and the cold list is full.

3. The storage system of claim 1, wherein the processor is configured to add the page ID to the cold list by inserting the page ID in a tail of the cold list.

4. The storage system of claim 1, wherein the processor is configured to:
produce a cold list that is a cold hash table;
determine a page ID hash using the page ID and a hash function; and
add the page ID to cold list by inserting the page ID into the cold hash table using the page ID hash as an index into the cold hash table.

5. The storage system of claim 4, wherein the processor is configured to:
insert the page ID into the cold hash table when a cold hash table entry indexed by the page ID hash is empty; and
concatenate the page ID to a previous page ID previously stored at the cold hash table entry indexed by the page ID hash when the cold hash table entry is not empty.

6. The storage system of claim 4, wherein the processor is configured to discard the page ID when a cold hash table entry indexed by the page ID hash is not empty and the cold hash table is full.

7. The storage system of claim 4, wherein the processor is configured to include a timestamp of the memory operation with the page ID in the cold hash table.

8. A method of operating a storage system, the method comprising:
receiving a memory operation at the storage system, wherein the memory operation includes a memory address;
adding a page identifier (ID) of a page of memory containing the memory address to a cold list when the page ID is not already in the cold list, wherein the cold list includes memory pages accessed less frequently than other memory pages;
removing the page ID from the cold list when the page ID is already in the cold list; and
omitting the adding the page ID to the cold list when the page ID is not already in the cold list and the cold list is full.

9. The method of claim 8, wherein adding the page ID to the cold list includes inserting the page ID to a tail of the cold list.

10. The method of claim 8, wherein the removing the page ID from the cold list includes removing the page ID from the cold list and adding the page ID to a linked cold list.

11. The method of claim 8, wherein the adding the page ID to the cold list includes adding the page ID to a cold list stored in content addressable memory (CAM) of the memory device.

12. The method of claim 8, wherein the adding the page ID to the cold list includes inserting the page ID into a cold hash table.

13. The method of claim 12, wherein the inserting the page ID into the cold hash table includes:
determining a page ID hash using the page ID and a hash function; and
inserting the page ID into the cold hash table using the page ID hash as an index into the cold hash table.

14. The method of claim 13, wherein the inserting the page ID into the cold hash table includes:
inserting the page ID into the cold hash table when a cold hash table entry indexed by the page ID hash is empty; and
concatenating the page ID to a previous page ID previously stored at the cold hash table entry indexed by the page ID hash when the cold hash table entry is not empty.

15. The method of claim 14, including discarding the page ID when the cold hash table entry is not empty and the cold hash table is full.

16. The method of claim 13, wherein the inserting the page ID into the cold hash table includes inserting the page ID and a timestamp of the memory operation in a cold hash table entry indexed by the page ID hash.

17. The method of claim 8, including:
receiving a request at the storage system from a host device to read at least a portion of the cold list; and
receiving a memory operation from the host device to move a page of memory having a page ID included in the cold list from a first type of memory to a second type of memory, wherein access to the first type of memory has lower latency than access to the second type of memory.

18. A host system comprising:
a host device including a host processor; and
a storage system including:
at least a first memory array having a first type of memory cells and a second memory array having a second type of memory cells, wherein latency to access the first memory is less than latency to access the second memory; and
a memory controller configured to:
receive a memory operation from the host processor, wherein the memory operation includes a memory address;
add a page identifier (ID) of a page of memory containing the memory address to a cold list when the page ID is not already in the cold list, wherein the cold list includes memory pages access less frequently than other memory pages;
remove the page ID from the cold list when the page ID is already in the cold list; and
omit the adding the page ID to the cold list when the page ID is not already in the cold list and the cold list is full.

19. The host system of claim 18, wherein the host processor is configured to move the page of memory from the first memory to the second memory in response to the page ID being added to the cold list.

20. The host system of claim 18, wherein the memory controller is configured to:
determine a page ID hash using the page ID and a hash function; and
insert the page ID with a timestamp into an element of the cold list indexed in the cold list using the page ID hash when the page ID is not already in the cold list.
